(19) United States
(12) Patent Application Publication
(10) Pub. No.: US 2013/0039002 A1
(43) Pub. Date: Feb. 14, 2013

(54) SERVER RACK ASSEMBLY

(71) Applicants: HAN-YU LI, Tu-Cheng (TW); NING ZHANG, Shenzhen City (CN); DA-HONG LONG, Shenzhen City (CN); GUANG-DONG HE, Shenzhen City (CN)

(72) Inventors: HAN-YU LI, Tu-Cheng (TW); NING ZHANG, Shenzhen City (CN); DA-HONG LONG, Shenzhen City (CN); GUANG-DONG HE, Shenzhen City (CN)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/455,233

(22) Filed: Apr. 25, 2012

(30) Foreign Application Priority Data
Aug. 9, 2011 (CN) 201110227151.7

(51) Int. Cl. H05K 7/20; H05K 7/14

(52) U.S. Cl. 361/679.48; 361/679.02

(57) ABSTRACT

A server rack assembly includes a server rack, a power supply device, and a bus-bar electronically connected to the power supply device. The server rack includes a bottom plate and a post substantially perpendicular to the bottom plate. The power supply device is attached to the post in a first direction that is substantially parallel to the bottom plate. The bus-bar includes a plurality of connectors adapted to electronically connect a plurality of servers. The bus-bar is attached to the post in a second direction that is substantially perpendicular to the bottom plate, and the plurality of connectors are arranged on the bus-bar in the second direction.

### BACKGROUND

1. Technical Field

The present disclosure relates to electronic devices, more particularly to a server rack assembly.

2. Description of Related Art

Blade and rack-mounted servers are popular form factors for data center servers. In order to achieve high performance, many rack-mounted servers are clustered in an enclosure. A server rack assembly may include a server rack and a plurality of servers received in the server rack. A height of each of the plurality of servers is 1U (1U=1.75 inch), and a height of the server rack is 42U. Each of the plurality of servers is connected to a power supply by a plurality of cables. Thus, a plurality of power supplies and a plurality of cables are received in the server rack. It can be confusing during maintenance because of the plurality of power supply and the plurality of cables. Therefore, an improved server rack assembly may be needed within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of a server rack assembly in accordance with an embodiment.

FIG. 2 is similar to FIG. 1, and a plurality of first and second servers of the server rack assembly is received in a server rack of the server rack assembly.

FIG. 3 is a rear view of the FIG. 2.

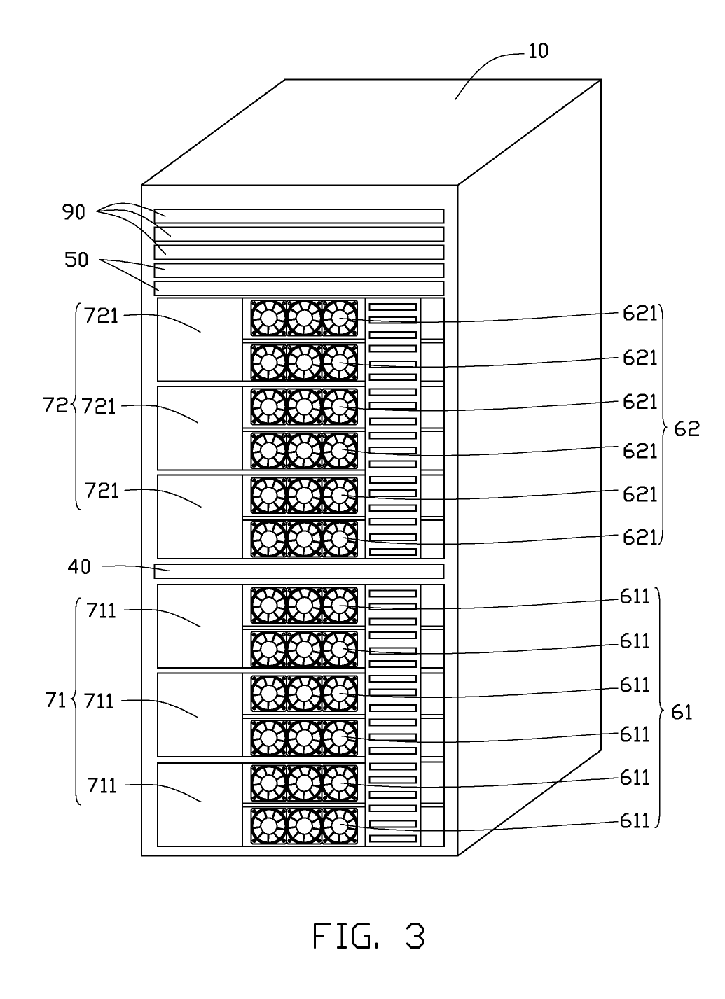

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

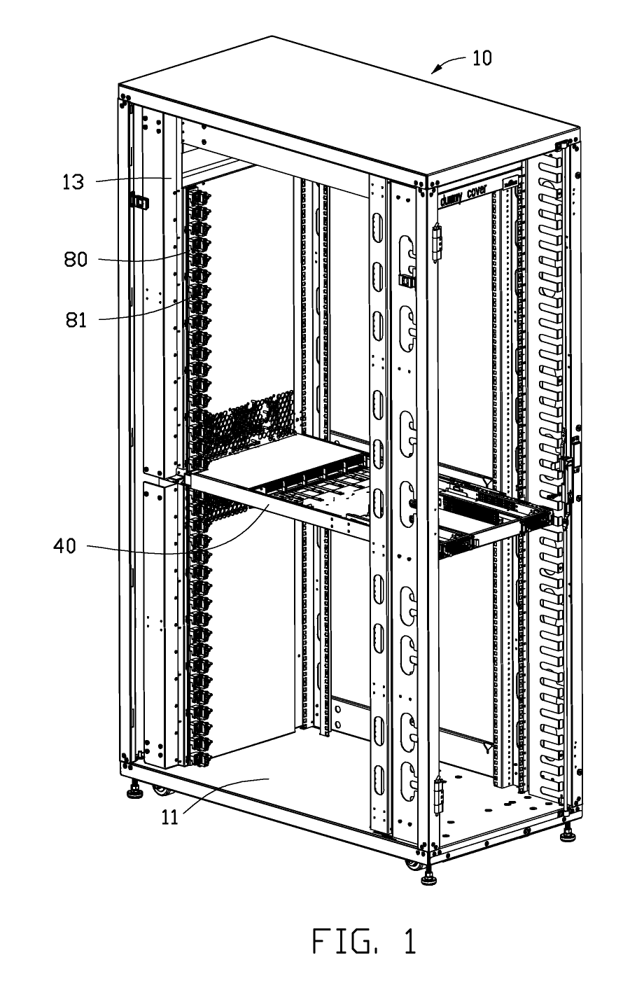

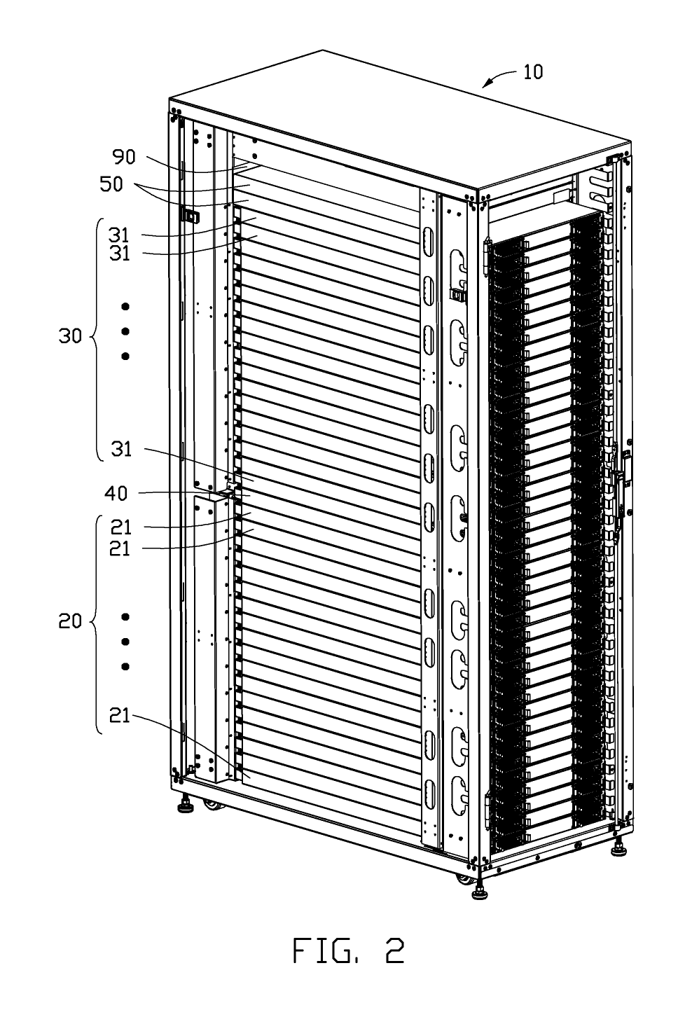

FIGS. 1 and 2, show a server rack assembly in accordance with an embodiment including a server rack 10, a first server assembly 20, a second server assembly 30, a power supply device 40, two exchangers 50, a first fan assembly 61, a second fan assembly 62, a first transferring circuit board assembly 71, a second transferring circuit board assembly 72. The power supply device 40 is located between the first server assembly 20 and the second server assembly 30. The two exchangers 50 are above the second server assembly 30. The first fan assembly 61 removes the heat generated from the first server assembly 20. The second fan assembly 62 removes the heat generated from the second server assembly 30. In one embodiment, a height of the server rack 10 is 42U.

The server rack 10 includes a bottom plate 11 and four posts 13 connected to the bottom plate 11. In one embodiment, each of the four posts 13 is substantially perpendicular to the bottom plate 11.

The first server assembly 20 includes a plurality of first servers 21. The second server assembly 30 includes a plurality of second servers 31. In one embodiment, the plurality of first servers 21 includes eighteen of the first servers 21, and the plurality of second servers 31 includes eighteen second servers 31. A height of each of the plurality of first servers 21 is 1U, and a height of each of the plurality of second servers 31 is 1U.

The power supply device 40 is secured to the four posts 13, and a bus-bar 80 is electronically connected to the power supply device 40. In one embodiment, the power supply device 40 is substantially parallel to the bottom plate 11, and the bus-bar 80 is arranged with one of the four posts 13 in a direction substantially perpendicular to the bottom plate 11.

The bus-bar 80 includes a plurality of first connectors 81 and a plurality of second connectors (not shown). Each of the plurality of first connectors 81 is electronically connected to each of the plurality of first and the plurality of second servers 21, 31. In one embodiment, a cross-section of the bus-bar 80 is a rectangle, and the bus-bar 80 is a copper bar. The plurality of first connectors 81 is equidistant arranged on the bus-bar 80 with a distance, between every adjacent two of the plurality of first connectors 81, being 1U.

The first fan assembly 61 includes a plurality of first fans 611, and each of the plurality of first fans 611 is electronically connected to the bus-bar 80 by a first part of the plurality of the second connectors. The second fan assembly 62 includes a plurality of second fans 621, and each of the plurality of second fans 621 is electronically connected to the bus-bar 80 by a second part of the plurality of second connectors. In one embodiment, the plurality of first fans 611 include six of the first fans 611, and the plurality of second fans 621 include six of the second fans 621. A height of each of the plurality of first fans 611 is 3U, and a height of each of the plurality of second fans 621 is also 3U. Therefore, each of the plurality of first fans 611 can communicate with three of the first servers 21, and each of the plurality of second fans 621 can communicate with three of the second servers 31.

The first transferring circuit board assembly 71 includes a plurality of first transferring circuit boards 711. Each of the plurality of first transferring circuit boards 711 is electronically connected to the plurality of first fans 611 and the plurality of first servers 21, to guide power from the plurality of first servers 21 to the plurality of first fans 611. The second transferring circuit board assembly 72 includes a plurality of second transferring circuit boards 721. Each of the plurality of second transferring circuit boards 721 is electronically connected to the plurality of second fans 621 and the plurality of second servers 31, to guide power from the plurality of second servers 31 to the plurality of second fans 621. In one embodiment, the plurality of first transferring circuit boards 711 include three of the first transferring circuit boards 711, and the plurality of second transferring circuit boards 721 include three of the second transferring circuit boards 721. A height of each of the plurality of first transferring circuit boards 711 is 6U, and a height of each of the plurality of second transferring circuit boards 721 is 6U. Therefore, each of the plurality of first transferring circuit boards 711 can communicate with two of the first fans 611 and six of the first servers 21, and each of the plurality of second transferring circuit boards 721 can communicate with two of the second fans 621 and six of the second servers 31. In one embodiment, each of the plurality of first transferring circuit boards 711 includes two first connectors connected to the two first fans 611 and six second connectors connected to the six first servers 21. Each of the plurality of second transferring circuit boards 721 has the same configuration as each of the plurality of first transferring circuit boards 711, and includes two first connectors connected to the two second fans 621 and six second connectors connected to the six second servers 31.

The two exchangers 50 can provide connections to the internet of the server rack system. In one embodiment, a height of each of the two exchangers 50 is 1U.

In use, a power generated by the power supply device 40 flows to the bus-bar 80, and flows through each of the plurality of first servers 21, each of the plurality of second servers 31, each of the plurality of first fans 611 and each of the plurality of second fans 621. Each of the plurality of first transferring circuit boards 711 is electronically connected to each of the plurality of first fans 611 and each of the plurality of first servers 21, and the plurality of first fans 611 can remove heat generated from the plurality of first servers 21. Each of the plurality of second transferring circuit boards 721 is electronically connected to each of the plurality of second fans 621 and each of the plurality of second servers 31, and the plurality of second fans 621 can remove heat generated from the plurality of second servers 31.

In addition, a receiving space 90 is defined above the two exchangers 50. A height of the receiving space 90 is 3U, and can receive three of the first servers 21 or three of the second servers 31.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A server rack assembly comprising:
a server rack comprising a bottom plate and a post substantially perpendicular to the bottom plate;
a power supply device attached to the post in a first direction substantially parallel to the bottom plate;
a bus-bar electronically connected to the power supply device; the bus-bar comprising a plurality of connectors adapted to electronically connect a plurality of servers;
wherein the bus-bar is attached to the post in a second direction substantially perpendicular to the bottom plate, and the plurality of connectors are arranged on the bus-bar in the second direction.

2. The server rack assembly of claim 1, wherein the plurality of connectors are divided into two parts by the power supply device.

3. The server rack assembly of claim 1, wherein a height of the power supply device is 1.75 inch, and the height of the power supply device is same as a height of each of the plurality of servers.

4. The server rack assembly of claim 3, further comprising a fan adapted to remove heat generated from the plurality of servers, wherein the fan is arranged on a side of the server rack in a direction substantially perpendicular to the power supply device.

5. The server rack assembly of claim 4, wherein a height of the fan is 3U, and a distance between every adjacent two of the plurality of connectors is 1U.

6. The server rack assembly of claim 4, further comprising a transferring circuit board, and the transferring circuit board is electronically connected to the fan.

7. The server rack assembly of claim 6, wherein a height of the transferring circuit board is 6U.

8. The server rack assembly of claim 1, wherein a cross-section of the bus-bar is a rectangle.

9. A server rack assembly comprising:
a server rack comprising a bottom plate and a post substantially perpendicular to the bottom plate;
a first server assembly comprising a plurality of first servers;
a second server assembly located above the first server assembly and comprising a plurality of second servers;
a power supply device located between the first server assembly and the second server assembly, wherein the power supply device is attached to the post in a first direction substantially parallel to the bottom plate;
a bus-bar electronically connected to the power supply device; the bus-bar comprising a plurality of connectors, each of the plurality of connectors is electronically connect to each of the plurality of first servers and each of the plurality of second servers;
wherein the bus-bar is attached to the post in a second direction is substantially perpendicular to the bottom plate, and the plurality of connectors are arranged on the bus-bar in the second direction.

10. The server rack assembly of claim 9, further comprising a first fan and a first transferring circuit board, the first fan being electronically connected to the bus-bar, and the first transferring circuit board being electronically connected to the first fan and the first server assembly, wherein a height of each of the plurality of first servers is 1.75 inch, a height of the first fan is 3U, and a height of the first transferring circuit board is 6U.

11. The server rack assembly of claim 10, wherein the first fan is arranged on a side of the server rack in a direction substantially perpendicular to the power supply device.

12. The server rack assembly of claim 10, wherein a distance between every adjacent two of the plurality of connectors is 1U.

13. The server rack assembly of claim 9, wherein the plurality of connectors are divided into two parts by the power supply device.

14. The server rack assembly of claim 9, wherein a cross-section of the bus-bar is a rectangle.

15. The server rack assembly of claim 14, further comprising two exchangers adapted to provide connections to the internet of the server rack system, wherein a height of each of the two exchangers is 1U.
